(19) United States
(12) Patent Application Publication
(10) Pub. No.: US 2018/0175185 A1
(43) Pub. Date: Jun. 21, 2018

(54) SEMICONDUCTOR DEVICE AND METHOD OF MANUFACTURING THE SAME

(71) Applicant: NATIONAL CHIAO TUNG UNIVERSITY, Hsinchu City (TW)

(72) Inventors: Edward Yi CHANG, Hsinchu County (TW); Shih-Chien LIU, Taoyuan City (TW); Chung-Kai HUANG, Kaohsiung City (TW); Chia-Hsun WU, Kaohsiung City (TW); Ping-Cheng HAN, Taichung City (TW); Yueh-Chin LIN, New Taipei City (TW); Ting-En HSIEH, Tainan City (TW)

(21) Appl. No.: 15/644,830

(22) Filed: Jul. 10, 2017

(30) Foreign Application Priority Data
Dec. 15, 2016 (TW) 105141643

(51) Int. Cl. H01L 29/778; H01L 29/51; H01L 21/28; H01L 29/40; H01L 29/423; H01L 29/66

(52) U.S. Cl. CPC H01L 29/7786; H01L 29/513; H01L 29/516; H01L 21/28291; H01L 29/205; H01L 29/42364; H01L 29/4236; H01L 29/66462; H01L 29/408

(57) ABSTRACT

A semiconductor device includes a substrate, a channel layer, a barrier layer, a recess, a charge trapping layer, a ferroelectric material layer, a gate, a source and a drain. The channel layer is disposed on the substrate. The barrier layer is disposed on the channel layer. The barrier layer has a recess, and a portion of the barrier layer under the recess has a thickness. The source and the drain are disposed on the barrier layer. The charge trapping layer covers the bottom of the recess. The ferroelectric material is disposed on the charge trapping layer. The gate is disposed on the ferroelectric material.

### RELATED APPLICATIONS

This application claims priority to Taiwan Application Serial Number 105141643, filed Dec. 15, 2016, which is herein incorporated by reference.

### BACKGROUND

### Field of Invention

The present invention relates to a semiconductor device and a method of manufacturing the same. More particularly, the present invention relates to a high electron mobility transistor.

### Description of Related Art

In semiconductor technologies, III-V compound semiconductors can be used to form a variety of integrated circuit devices, such as high power field effect transistors, high frequency transistors, and high electron mobility transistors (HEMTs). The III-V compound semiconductors have the potential to replace the semiconductor material of the traditional silicon transistors.

However, when the III-V compound semiconductor is gallium nitride or gallium oxide, the channel of the device is in the normally-on state. Since the threshold voltage of a normally-on transistor is a negative value, current in the transistor is still in the conducting state when the transistor is at zero gate bias and it causes an extra power loss. Currently, methods to solve this problem, such as thinning of the gallium nitride layer, ion implantation, or the use of p-type gallium oxide, propose approaches to increase the threshold voltage to a level of higher than 0V. However, the threshold voltage of the transistor should be more than 6V to prevent the abnormal turn-on caused by an unstable fluctuation of the gate voltage. Nowadays, most of the methods proposed by the academic and industrial fields provide ways to add additional circuits to resolve this issue. However, those methods cause the parasitic effect and result in the unnecessary energy loss. The conventional methods also cause the increase in manufacturing cost. The embodiments of the present application can increase the threshold voltage of the transistors to be more than 6V and allow the transistors to have excellent characteristics.

### SUMMARY

According to various embodiments of the present application, a semiconductor device is provided. The semiconductor device includes a substrate, a channel layer, a barrier layer, a recess, a charge trapping layer, a ferroelectric material, a gate, a source and a drain. The channel layer is disposed on the substrate. The barrier layer is disposed on the channel layer. The barrier layer has a recess, and a portion of the barrier layer under the recess has a thickness. The source and the drain are disposed on the barrier layer. The charge trapping layer covers the bottom of the recess. The ferroelectric material is disposed on the charge trapping layer. The gate is disposed over the ferroelectric material.

In some embodiments, the semiconductor device further includes a first dielectric layer disposed between the bottom surface of the recess and the charge trapping layer.

In some embodiments, the semiconductor device further includes a second dielectric layer disposed between the ferroelectric material layer and the gate.

In some embodiments, the first dielectric layer has a bandgap, and the bandgap ranges between 7 eV and 12 eV.

In some embodiments, the thickness of the portion of the barrier layer under the recess ranges between 5 nm and 15 nm.

In some embodiments, the ferroelectric material layer includes a layer made of BaTiO₃, KH₂PO₄, HfZrO₂, SrBi₂Ta₂O₉, or PbZrTiO₃.

According to various embodiments of the present application, the invention provides a method of manufacturing a semiconductor device. The method includes: providing a substrate; forming a channel layer on the substrate; forming a barrier layer on the channel layer; forming a source and a drain on the barrier layer; forming a recess in the barrier layer, the recess having a bottom surface and a portion of the barrier underneath the recess having a thickness; forming a charge trapping layer covering the bottom surface of the recess; forming a ferroelectric material layer on the charge trapping layer; heating the ferroelectric material layer to a first temperature, and the first temperature is higher than a crystallization temperature of the ferroelectric material layer; cooling down the ferroelectric material layer to a second temperature to crystallize the ferroelectric material layer; and forming a gate over the ferroelectric material layer.

In some embodiments, after forming the recess in the barrier layer, the method further includes forming a first dielectric layer covering the bottom of the recess.

In some embodiments, forming the ferroelectric material layer includes plasma enhanced atomic layer deposition, metal-organic chemical vapor deposition (MOCVD), chemical vapor deposition, physical vapor deposition, sputtering, or pulsed laser evaporation.

In some embodiments, the first temperature ranges between 400° C. and 600° C.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1, FIG. 2, FIG. 3, FIG. 4A, FIG. 4B and FIG. 4C are cross-sectional views illustrating various stages of the method of manufacturing a semiconductor device according to various embodiments of this invention.

FIG. 5A and FIG. 5B depict the I_{D}-V_{GS} curve of the semiconductor devices according to some embodiments of the invention.

### DESCRIPTION OF THE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of a semiconductor device and a method of manufacturing the semiconductor device are provided hereinafter. The structure and the characteristics of the semiconductor device and the steps or operations of manufacturing the semiconductor device are described in detail hereinafter.

In recent years, high electron mobility transistors (HEMTs) have been widely applied to high-power circuit systems due to the excellent characteristics, such as a high output power, a high breakdown voltage, and an excellent resistance to high temperatures. Since a large number of polarized charges exist between the channel layer and the barrier layer of the high electron mobility transistor known in the art, these polarized charges form a two dimensional electron gas (2DEG) and allow the electrons to have a high mobility. Under the circumstances, current in the transistor is still in the conducting state when no gate bias is applied to the transistor. The transistor is therefore called a normally-on transistor. The threshold voltage of normally-on transistor is a negative value. That is, current is still in the conducting state when the transistor is at zero gate bias and thereby causes an extra power loss. Additionally, the normally-on transistor does not possess fail-safe characteristics, and it therefore has potential danger. Accordingly, the development of a normally-off transistor is an important topic in the development of the high-power transistors. Further, the high-power circuit systems need to be operated at a high bias voltage, and it may easily generate instantaneous voltage pulses at the high bias voltage. If the threshold voltage of the transistor is not high enough, the high power component may easily be abnormally turned on and thereby causes the abnormal operation of the circuit and impacts the stability thereof. Hence, the present invention provides a high electron mobility transistor device having a high threshold voltage, which is a normally-off high electron mobility transistor, and it can retain high output current in the meanwhile.

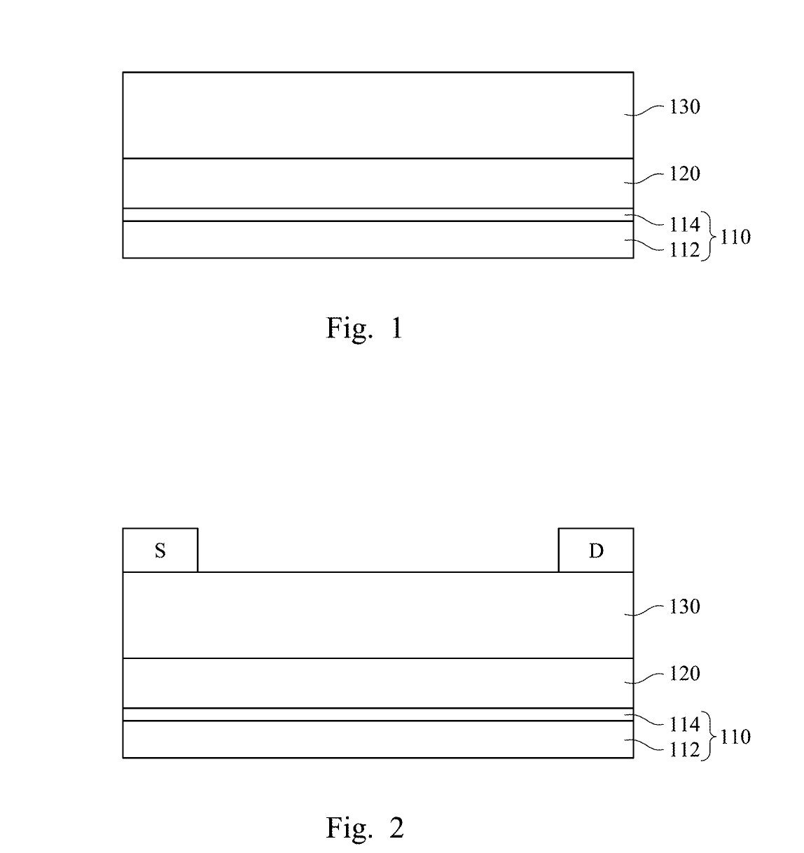

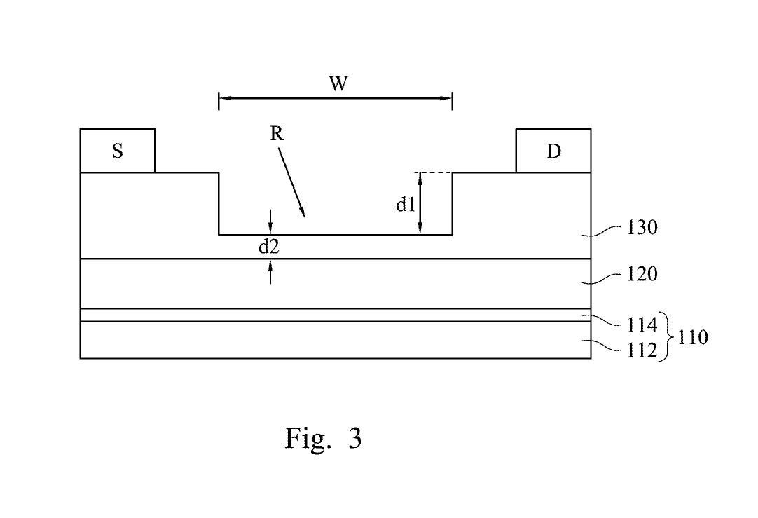

FIGS. 1-4C are cross-sectional views illustrating various stages of the method of manufacturing a semiconductor device according to various embodiments of this invention.

In FIG. 1, a substrate 110 is provided. The substrate 100 includes a base substrate 112 and a buffer layer 114. The buffer layer 114 is disposed on the base substrate 112. In examples, the base substrate 112 is a silicon (Si) substrate, a silicon carbide (SiC) substrate, a sapphire substrate, a gallium nitride (GaN) substrate, an aluminum gallium nitride (AlGaN) substrate, an aluminum nitride (AlN) substrate, a gallium phosphide (GaP) substrate, a gallium arsenide (GaAs) substrate, an aluminum gallium arsenide (AlGaAs) substrate, or other substrates including III-V compounds. In examples, the buffer layer 114 includes a layer of GaN or GaN having p-type dopants. The buffer layer 114 may be formed by epitaxial processes or other suitable processes. For example, the p-type dopants include carbon, iron, magnesium, zinc, or other suitable p-type dopants. The buffer layer 114 can lower leakage current and prevent the cracks in the channel layer 120 when forming the channel layer 120. In another embodiment, the substrate 110 includes a base substrate 112, a crystal seed layer (not shown) and a buffer layer 114. The crystal seed layer is disposed on the base substrate 112. The buffer layer 114 is disposed on the crystal seed layer. The crystal seed layer may facilitate to compensate the lattice mismatch between the base substrate 112 and the buffer layer 114.

A channel layer 120 is then formed on the substrate 110. Next, a barrier layer 130 is formed on the channel layer 120. In examples, the channel layer 120 may be a layer made of AlGaN, GaN, indium gallium nitride (InGaN), aluminum indium gallium nitride (AlInGaN), or compounds including III-V elements. In examples, the barrier layer 130 includes a layer of AlN, aluminum indium nitride (AlInN), AlGaN, GaN, InGaN, AlInGaN, or compounds including III-V elements. The band gap of the channel layer120 is less than the band gap of the barrier layer 130. The selection of the materials and the thicknesses of the channel layer 130 and the barrier layer 130 should be able to generate a two dimensional electron gas. In one example, each of the channel layer 120 and the barrier layer 130 may be a multi-layered structure. In another embodiment, some other layers may be further formed. For example, an intermediate layer (not shown) may be formed between the channel layer 120 and the barrier layer 130. A doped layer (not shown) may be formed on the barrier layer 130 to increase electrons of the two dimensional electron gas. A capping layer (not shown) may be formed on the barrier layer 130 to prevent the barrier layer 130 from oxidization.

Referring to FIG. 2, a source S and a drain D are formed on the barrier layer 130. In examples, the material of each of the source S and the drain D is selected from, but not limited to, the group consisting of silver (Ag), copper (Cu), tungsten (W), titanium (Ti), tantalum (Ta), aluminum (Al), nickel (Ni), ruthenium (Ru), palladium (Pd), platinum (Pt), manganese (Mn), tungsten nitride (WN), titanium nitride (TiN), tantalum nitride (TaN), aluminum nitride (AlN), tungsten silicide (WSi), molybdenum nitride (MoN), nickel silicide (Ni₂Si), titanium silicide (TiSi₂), titanium aluminide (TiAl), arsenic-doped (As-doped) polycrystalline silicon, zirconium nitride (ZrN), tantalum carbide (TaC), TaCN, TaSiN, titanium aluminium nitride (TiAlN), silicide, and any combination thereof. The source S and drain D may be formed by using any process known in the art.

As shown in FIG. 3, a recess R is formed in the barrier layer 130 by a patterning process. In one embodiment, a masking layer such as a hard mask layer or a photoresist layer may be formed on the barrier layer 130, and the masking layer is patterned. The pattern of the masking layer is transferred to the underneath barrier layer 130 by an etching process to form the recess R. In examples, the etching process may be a reactive ion etching process, a plasma dry etching process or other anisotropic etching processes. For example, the etching gas may be SF₆, SiCl₄, C₄F₈, CH₄, H₂, Ar, or other known etching gases, or a combination thereof. In another embodiment, the recess R is formed by a wet etching process after forming the masking layer to smooth the bottom corners of the recess R.

The recess R has a depth d1 and a width W. In some embodiments, the depth d1 ranges from 15 nm to 25 nm, such as 15 nm, 20 nm or 25 nm. The width W ranges from 0.1 μm to 3 μm, such as 0.5 μm, 1 μm, 2 μm or 2.5 μm. The recess R is disposed between the source S and the drain D, and the recess R does not penetrate through the barrier 130. The purpose of the recess R is to attenuate the polarization of the barrier layer 130 and eliminate the carriers of the two dimensional electron gas such that the threshold voltage may be more than 0V. A relatively thin barrier layer may raise the energy level of the conduction band. Therefore, decreasing in the thickness of the barrier layer underneath the gate region can deplete the two dimensional electron gas. The portion of the barrier layer 130 between the bottom surface of the recess R and the top surface of the channel layer 120 has a thickness d2. The thickness d2 ranges from 0 nm to 10 nm, such as 1 nm, 3 nm, 5 nm or 8 nm. It should be noticed that if the thickness d2 is thicker than 10 nm, the barrier layer 130 may have a large number of polarized charges and hence the channel turns into a normally-on state.

In some examples, the width W of the recess R is less than 3 μm, such as 0.05 μm, 0.5 μm, 1 μm or 2 μm. In examples, the distance between the recess R and the source S is different from the distance between the recess R and the drain D. For example, the distance between the edge of the recess R and the source S ranges from 1 μm to 3 μm, such as 1.5 μm, 2 μm or 2.5 μm. The distance between the edge of the recess R and the drain D ranges from 5 μm to 15 μm, such as 7.5 μm, 10 μm or 12.5 μm.

FIGS. 4A-4C illustrate different embodiments of the ferroelectric composite material layer. As shown in FIGS. 4A-4C, the ferroelectric composite material layer is formed in the recess R after the formation of the recess R. In some embodiments, the ferroelectric composite material layer may be formed by a plasma enhanced atomic layer deposition process, a metal-organic chemical vapor deposition (MOCVD) process, a chemical vapor deposition process, a physical vapor deposition process, a sputtering process, or pulsed laser evaporation process. After forming the ferroelectric composite material layer, a patterning process may optionally be used to trim the ferroelectric composite material layer such that the sidewalls of the ferroelectric composite material layer are aligned with the sidewalls of the recess R. In examples, the width of the ferroelectric composite material layer is equal to the width W of the recess R.

In FIG. 4A, the ferroelectric composite material layer includes a charge trapping layer 220 (or so-called a charge storage layer) and a ferroelectric material layer 230. The charge trapping layer 220 covers the bottom surface of the recess R. The ferroelectric material layer 230 is disposed on the charge trapping layer 220. The gate 250 is disposed over the ferroelectric material layer 230. The passivation layer 260 covers a portion of the barrier layer 130. In examples, the charge trapping layer 220 may include a nanocrystal layer embedded in an insulating material, or a dielectric layer made of silicon nitrides, HfON, HfO₂ or ZrO₂. The thickness of the charge trapping layer 220, for example, ranges from 1 nm to 4 nm, such as 1.5 nm, 2 nm, 2.5 nm or 3 nm. The thickness of the charge trapping layer 220 depends on the characteristics of the chosen material. In one example, the charge trapping layer 220 is a multi-layered structure which may include any combination of the foregoing materials of the charge trapping layer 220. In one example, the passivation layer 260 may include AlN, Al₂O₃, AlON, SiN, SiO₂, SiON or Si₃N₄.

In various examples, the ferroelectric material layer 230 includes a layer made of BaTiO₃, KH₂PO₄, HfZrO₂, SrBi₂Ta₂O₉ (SBT), PbZrTiO3 (PZT) or other materials that can trigger the ferroelectric effect. The ferroelectric material refers to a material having characteristics of spontaneous polarization and polarization transition in an external electric field. The ferroelectric effect refers to an effect that electric dipoles will align with the direction of an electric field when the external electric field is applied, and the remnant polarization (Pr) in the polarization direction is still retained after the removal of the external electric field. For any ferroelectric material, the remnant polarization indicates that the ferroelectric material has a characteristic of permanent polarization. After the formation of the ferroelectric material layer 230, a thermal annealing process is performed to treat the ferroelectric material layer 230. The ferroelectric material layer 230 is heated to a first temperature, and the first temperature is higher than the crystallization temperature (Tc) thereof. The ferroelectric material layer 230 is then cooled down to a second temperature to crystallize the ferroelectric material layer 230 and become a material having the ferroelectric effect. In examples, the first temperature ranges between 400° C. and 600° C., such as 450° C., 500° C. or 550° C. The second temperature ranges between 25° C. and 100° C., such as 25° C. or 80° C.

In FIG. 4B, another embodiment of the ferroelectric composite material layer is provided. In the embodiment, a first dielectric layer 210 is firstly formed in the recess R. The charge trapping layer 220 is then formed on the first dielectric layer 210. Next, the ferroelectric material layer 230 is formed on the charge trapping layer 220. Afterwards, the gate 250 is formed on the ferroelectric material layer 230. The passivation layer 260 covers the barrier layer 130. The first dielectric layer 210 functions as a barrier layer with a wide bandgap. The bandgap of the first dielectric layer 210 is between 7 eV and 12 eV, such as 8 eV, 9 eV, or 11 eV. The first dielectric layer 210 may decrease leakage current of the semiconductor device and increase the breakdown voltage of the gate 250. The first dielectric layer 210 includes a layer of Al₂O₃, SiO₂ or other materials having bandgaps between 7 eV and 12 eV. The methods of forming the charge trapping layer 220 and the ferroelectric material layer 230 may be the same as these described hereinbefore in connection with FIG. 4A, and are not repeated herein.

In FIG. 4C, another embodiment of the ferroelectric composite material layer is provided. The ferroelectric composite material layer includes the first dielectric layer 210, the charge trapping layer 220, the ferroelectric material layer 230 and a second dielectric layer 240. The first dielectric layer 210 is disposed in the recess R. The charge trapping layer 220 is disposed on the first dielectric layer 210. The ferroelectric material layer 230 is disposed on the charge trapping layer 220. The second dielectric layer 240 is disposed on the ferroelectric material layer 230. The gate 250 is disposed on the second dielectric layer 240. The passivation layer 260 covers the barrier layer 130. The first dielectric layer 210 and the second dielectric layer 240 function as barrier layers having wide bandgaps. The bandgap of each of the first dielectric layer 210 and the second dielectric layer 240 is between 7 eV and 12 eV, such as 8 eV, 9 eV, or 11 eV. The first dielectric layer 210 and the second dielectric layer 240 may decrease leakage current of the semiconductor device and increase the breakdown voltage of the gate 250. The second dielectric layer 240 includes a layer of Al₂O₃, SiO₂ or other materials having bandgaps between 7 eV and 12 eV.

In the semiconductor devices of the present application, when a positive voltage is applied to the gate 250, and the ferroelectric material layer 230 may be polarized and collect charges. The charge trapping layer 220 provides a place for storing the charges. Meanwhile, the bandgaps of the channel layer 120 and the barrier layer 130 underneath the gate 250 and the ferroelectric composite material layer begin to change, and further the negative electric potential of the surface of the barrier layer 130 increases, thereby increasing the threshold voltage of the semiconductor device to a positive value.

In one embodiment, after the ferroelectric material layer 230 is polarized, the delta value of the threshold voltages of the semiconductor device may be larger than 5V. The threshold voltage of the semiconductor device changes from about 0V to a value larger than 5V. That is, the semiconductor device becomes an enhanced semiconductor device. In another embodiment, the threshold voltage may be tuned by adjusting the depth of the recess R. In the condition where the thicknesses (d1+d2) of the barrier layer is kept the same, a thinner thickness d2 may result in a larger positive value of the threshold voltage. However, the maximum of drain current may be unfavorably decreased when thinning down the thickness d2, and hence the value of the thickness d2 should be controlled in a certain range.

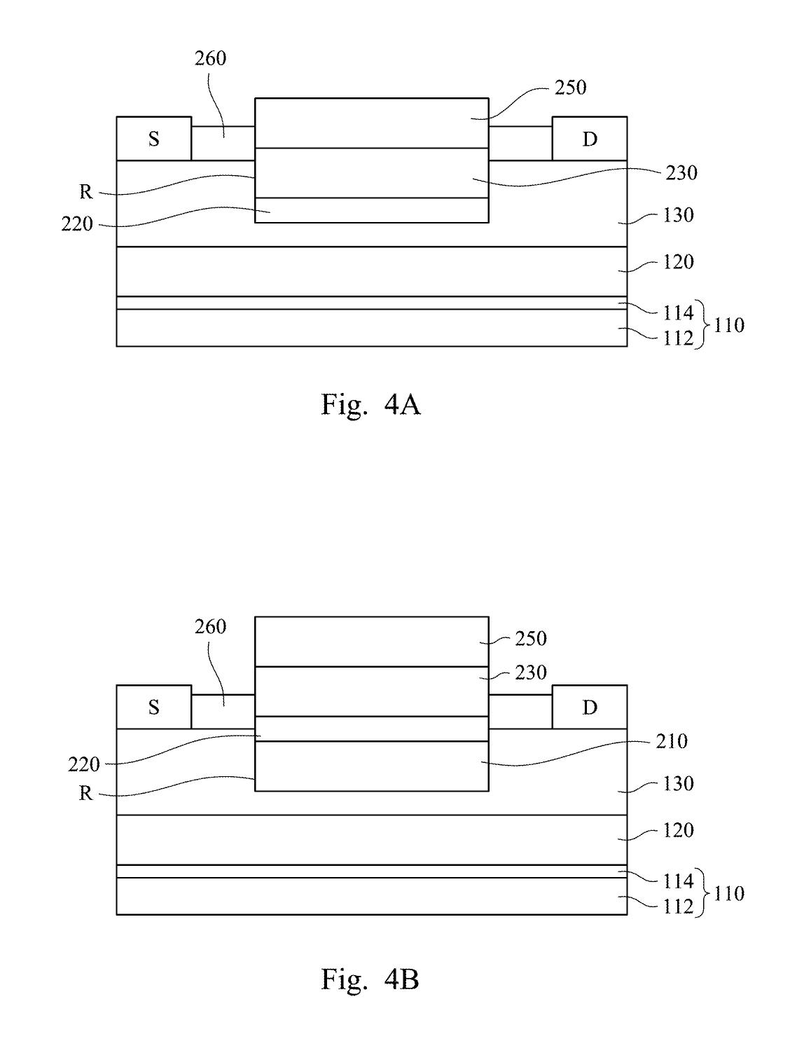

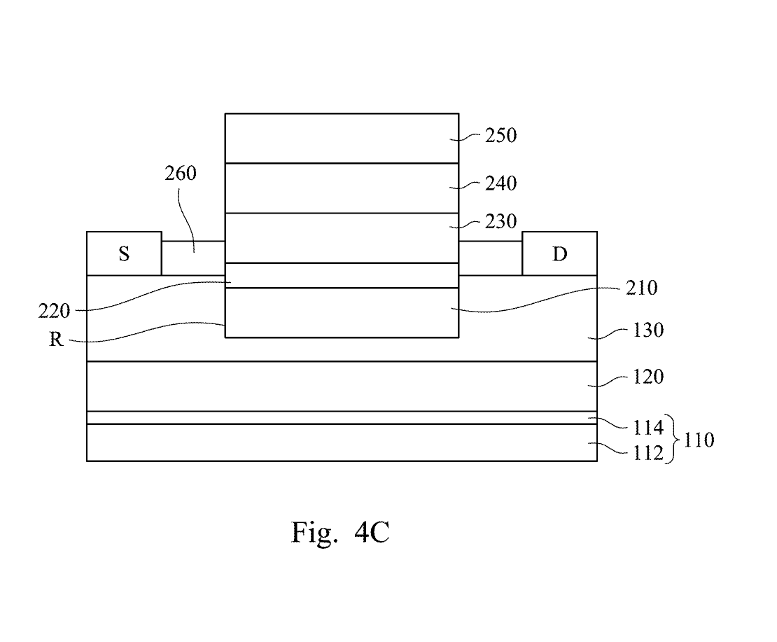

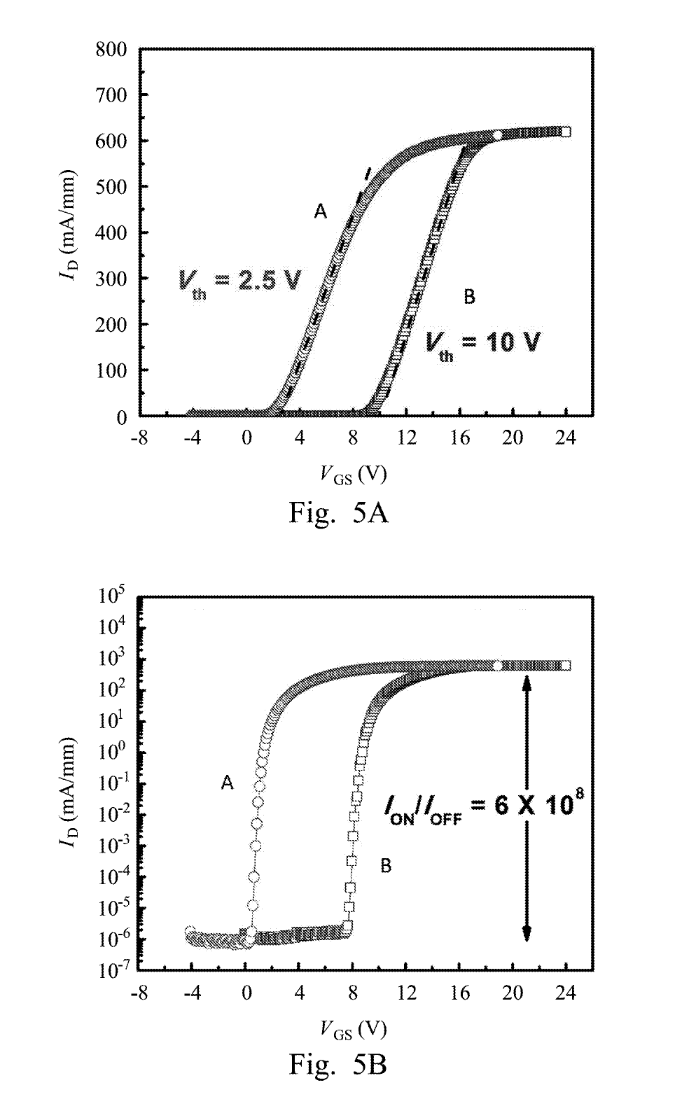

FIGS. 5A and 5B are I_{D}-V_{GS} curves of the semiconductor devices in accordance with some embodiments of the present disclosure. In FIGS. 5A and 5B, curve A represents data associated with the ferroelectric material layer 230 before polarization, and curve B represents data associated with the ferroelectric material layer 230 after polarization. As shown in FIG. 5A, the threshold voltage of the semiconductor device changes from 2.5V to 10V after the polarization of the ferroelectric material layer 230. As shown in FIG. 5B, the Iₒₙ/I_{off} ratio of the semiconductor device is 6×10⁸.

In summary, the various embodiments of the present application provide a semiconductor device that utilizes the polarization of the ferroelectric material layer to change the bandgaps of the channel layer and the barrier layer. Therefore, the semiconductor device may have a relatively higher threshold voltage to attenuate extra power loss and improve the stability of the circuit system.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device comprising:
a substrate;
a channel layer disposed on the substrate;
a barrier layer disposed on the channel layer, the barrier layer having a recess, wherein the barrier layer has a portion underneath the recess, and the portion has a thickness;
a source and a drain disposed on the barrier layer;
a charge trapping layer covering a bottom surface of the recess;
a ferroelectric material layer disposed on the charge trapping layer; and
a gate disposed over the ferroelectric material.

2. The semiconductor device of claim 1, further comprising a first dielectric layer disposed between the bottom surface of the recess and the charge trapping layer.

3. The semiconductor device of claim 1, further comprising a second dielectric layer disposed between the ferroelectric material layer and the gate.

4. The semiconductor device of claim 2, wherein the first dielectric layer has a bandgap, and the bandgap ranges between 7 eV to 12 eV.

5. The semiconductor device of claim 1, wherein the thickness of the portion of the barrier layer ranges between 5 nm and 15 nm.

6. The semiconductor device of claim 5, wherein the ferroelectric material layer comprises a layer made of BaTiO3, KH2PO4, HfZrO2, SrBi2Ta2O9 or PbZrTiO3.

7-10. (canceled)
